(19) United States
(12) Patent Application Publication
(10) Pub. No.: US 2026/0239984 A1
(43) Pub. Date: Aug. 13, 2026

(54) SEMICONDUCTOR DEVICE AND SWITCHING CIRCUIT

(71) Applicants: ROHM CO., LTD., Kyoto (JP); Ancora Semiconductors Inc., Taoyuan City (TW)

(72) Inventors: Takumi FUJIMAKI, Kyoto (JP); Satoru NATE, Kyoto (JP); Ying-Chen LIU, Taoyuan City (TW); Wei-Hsiang CHAO, Taoyuan City (TW)

(21) Appl. No.: 19/457,881

(22) Filed: Jan. 23, 2026

(30) Foreign Application Priority Data
Jan. 29, 2025 (JP) 2025-012859

(51) Int. Cl. H10W 40/80; H10D 62/85; H10D 80/30; H10W 40/50; H10W 90/00

(52) U.S. Cl. CPC H10W 40/80; H10D 80/30; H10W 40/50; H10D 62/8503; H10W 90/753

(57) ABSTRACT

A semiconductor device includes a GaN chip and a Si chip. The GaN chip includes a GaN power element and a temperature monitoring element. The Si chip includes: a drive circuit configured to drive the GaN power element; and a protection circuit configured to generate a thermal shutdown protection signal using an output of the temperature monitoring element.

### CROSS-REFERENCE TO RELATED APPLICATIONS

This nonprovisional application claims priority under 35 U.S.C. § 119(a) on Patent Application No. 2025-012859 filed in Japan on Jan. 29, 2025, the entire contents of which are hereby incorporated by reference.

### BACKGROUND OF THE INVENTION

### 1. Technical Field

The present disclosure relates to semiconductor devices and switching circuits.

### 2. Description of Related Art

In recent years, semiconductor devices which include gallium nitride (GaN) power elements have been increasingly commercialized (see, for example, Japanese Unexamined Patent Application Publication No. 2024-70020).

### BRIEF DESCRIPTION OF THE DRAWINGS

FIG. 1 is a diagram showing the configuration of a semiconductor device according to Comparative Example;

FIG. 2 is a diagram showing the temperature changes of a GaN chip and a Si chip in the semiconductor device according to Comparative Example;

FIG. 3 is a diagram showing the configuration of a semiconductor device according to an embodiment;

FIG. 4 is a timing chart showing waveforms of voltages and currents at parts of the semiconductor device according to the embodiment;

FIG. 5 is a perspective view of the appearance of the semiconductor device according to the embodiment; and

FIG. 6 is a diagram showing a schematic configuration of a step-up DC/DC converter.

### DETAILED DESCRIPTION

In the present specification, a MOS (Metal Oxide Semiconductor) field effect transistor refers to a field effect transistor in which the structure of a gate includes at least three layers of “a layer formed of a conductor or a semiconductor such as polysilicon with a low resistance value”, “an insulating layer” and “a p-type, n-type or intrinsic semiconductor layer”. In other words, the structure of the gate of the MOS field effect transistor is not limited to a three-layer structure of metal, oxide and semiconductor.

In the present specification, a constant current means a current which is constant under ideal conditions, but actually refers to a current which may fluctuate slightly due to a temperature change or the like. In other words, the constant current has a temperature characteristic which is flat or can be regarded as being flat.

In the present specification, a constant voltage means a voltage which is constant under ideal conditions, but actually refers to a voltage which may fluctuate slightly due to a temperature change or the like. In other words, the constant voltage has a temperature characteristic which is flat or can be regarded as being flat.

In the present specification, a reference voltage means a voltage which is constant under ideal conditions, but actually refers to a voltage which may fluctuate slightly due to a temperature change or the like. In other words, the reference voltage has a temperature characteristic which is flat or can be regarded as being flat.

### Comparative Example

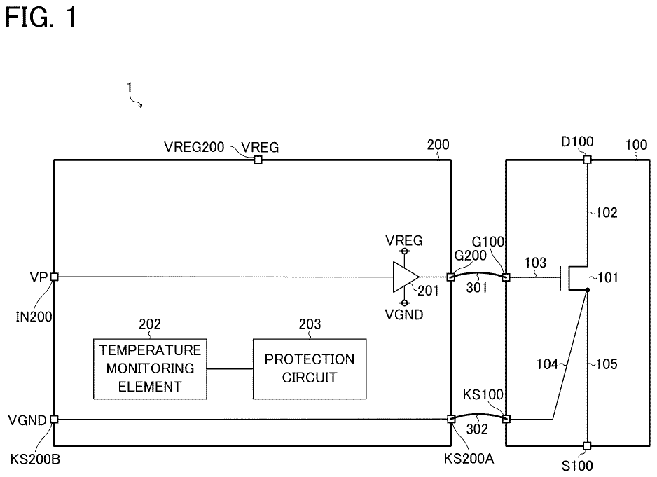

FIG. 1 is a diagram showing the configuration of a semiconductor device 1 according to Comparative Example (=a general configuration to be compared with an embodiment which will be described later).

The semiconductor device 1 includes a GaN chip 100 and a silicon (Si) chip 200.

The GaN chip 100 includes a GaN power element 101, wires 102 to 105, a pad D100, a pad G100, a pad KS100 and a pad S100.

The GaN power element 101 is, for example, a GaN high electron mobility transistor (HEMT). The drain of the GaN power element 101 is electrically connected to the pad D100 via the wire 102 in the GaN chip 100. The gate of the GaN power element 101 is electrically connected to the pad G100 via the wire 103 in the GaN chip 100. The source of the GaN power element 101 is electrically connected to the pad KS100 via the wire 104 in the GaN chip 100, and is electrically connected to the pad S100 via the wire 105.

The Si chip 200 includes a driver 201, a temperature monitoring element 202, a protection circuit 203, a pad IN200, a pad G200, a pad KS200A, a pad KS200B and a pad VREG200.

The pad G200 provided in the Si chip 200 is electrically connected by a bonding wire 301 to the pad G100 provided in the GaN chip 100. The pad KS200A provided in the Si chip 200 is electrically connected by a bonding wire 302 to the pad KS100 provided in the GaN chip 100.

The input end of the driver 201 is electrically connected to the pad IN200 in the Si chip 200. The output end of the driver 201 is electrically connected to the pad G200 in the Si chip 200. The pads KS200A and KS200B are electrically connected to each other in the Si chip 200. A constant voltage VREG which is applied to the pad VREG200 is supplied to the positive power supply ends of the driver 201 and the protection circuit 203, and a ground voltage VGND which is applied to the pad KS200B is supplied to the negative power supply ends of the driver 201 and the protection circuit 203. The driver 201 drives the GaN power element 101 based on the pulse voltage VP applied to the pad IN200. The protection circuit 203 generates a thermal shutdown protection signal using the output of the temperature monitoring element 202. For example, the thermal shutdown protection signal stops the operation of the driver 201. For example, a switch for switching the energization and interruption of the constant voltage VREG to the positive power supply end of the driver 201 may be provided, and the switch may be controlled by the thermal shutdown protection signal to interrupt the constant voltage VREG to the positive power supply end of the driver 201.

In the semiconductor device 1 configured as described above, the protection circuit 203 applies thermal shutdown protection based on the temperature of the Si chip 200 monitored by the temperature monitoring element 202.

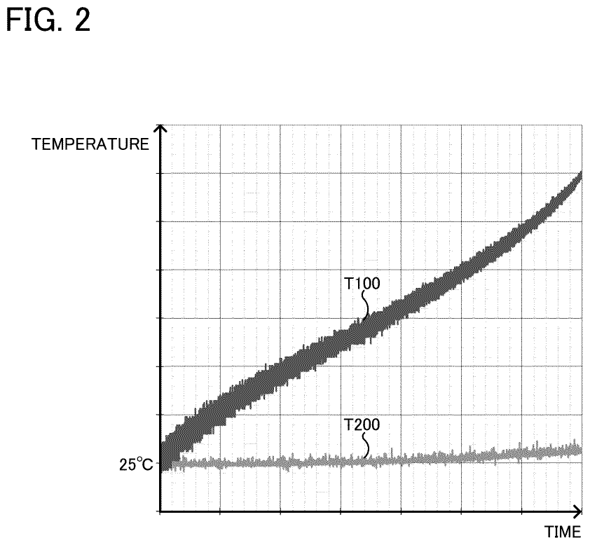

Here, when the temperature of the GaN power element 101 rises, from room temperature (25° C.) to a temperature at which thermal shutdown protection needs to be applied, at a rate of about several milliseconds to several tens of milliseconds, a temperature change T100 of the GaN chip 100 and a temperature change T200 of the Si chip 200 are as shown in FIG. 2. When as shown in FIG. 2, the temperature rise of the Si chip 200 cannot keep up with the temperature rise of the GaN chip 100, in the semiconductor device 1 configured as described above, the thermal shutdown protection to be performed by the protection circuit 203 is not applied for a long time, and thus it is likely that the GaN power element 101 is thermally destroyed before the thermal shutdown protection is applied by the protection circuit 203.

### Embodiment

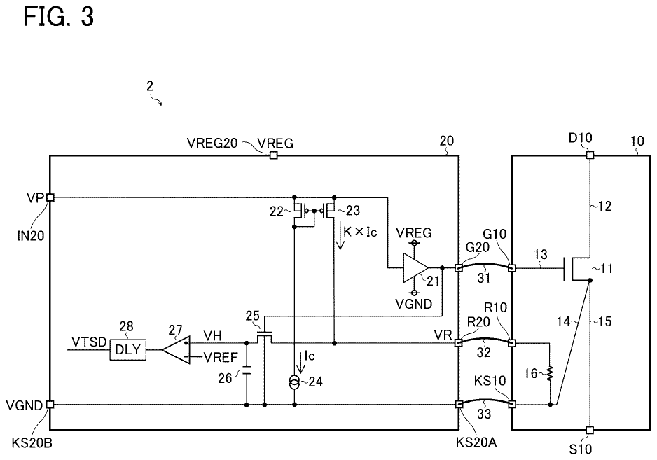

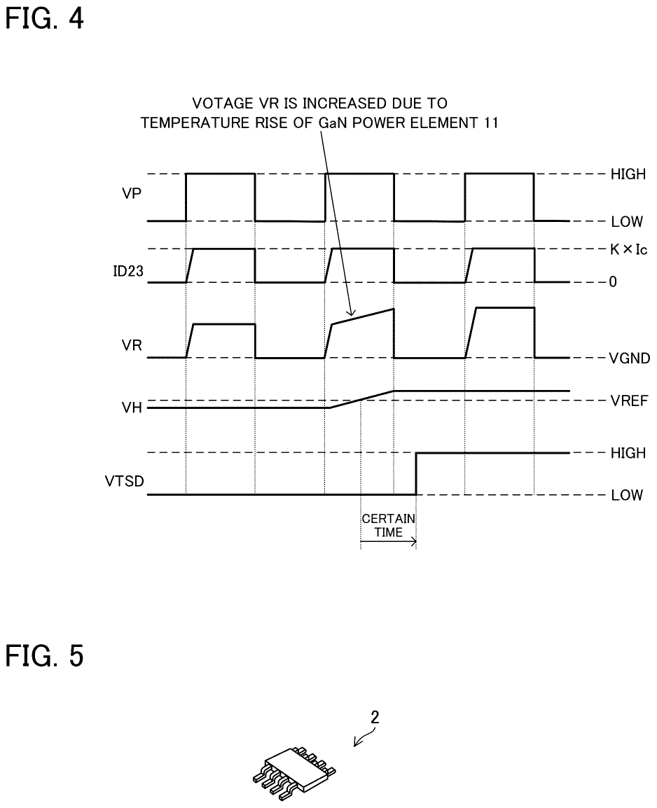

FIG. 3 is a diagram showing the configuration of a semiconductor device 2 according to an embodiment. FIG. 4 is a timing chart showing waveforms of voltages and currents at parts of the semiconductor device 2. A current ID23 in FIG. 4 means a drain current of a P-channel MOS field effect transistor 23 which will be described later. FIG. 5 is a perspective view of the appearance of the semiconductor device 2. The semiconductor device 2 is an electronic component formed by sealing a GaN chip 10 and a Si chip 20 which will be described later in a housing (package) made of resin. In the housing of the semiconductor device 2, a plurality of external terminals are provided to be exposed, and the external terminals include five external terminals which are electrically connected to pads D10, S10, IN20, KS20B and VREG20 shown in FIG. 3, respectively. The number of external terminals in the semiconductor device 2 shown in FIG. 5 and the appearance of the semiconductor device 2 are merely examples.

The semiconductor device 2 shown in FIG. 3 includes the GaN chip 10 and the Si chip 20. The GaN chip 10 is formed, for example, by cutting a GaN thin film formed on a silicon substrate or a sapphire substrate into chip shapes. The GaN chip 10 may be formed, for example, by cutting a GaN substrate into chip shapes. The Si chip 20 is formed, for example, by cutting a silicon substrate into chip shapes.

The GaN chip 10 includes a GaN power element 11, wires 12 to 15, a temperature monitoring element 16, a pad D10, a pad G10, a pad R10, a pad KS10 and a pad S10.

The GaN power element 11 is, for example, a GaN high electron mobility transistor. The drain of the GaN power element 11 is electrically connected to the pad D10 via the wire 12 in the GaN chip 10. The gate of the GaN power element 11 is electrically connected to the pad G10 via the wire 13 in the GaN chip 10. The source of the GaN power element 11 is electrically connected to the pad KS10 via the wire 14 in the GaN chip 10, and is electrically connected to the pad S10 via the wire 15.

The temperature monitoring element 16 is, for example, a resistance element formed of metal. When the temperature monitoring element 16 is, for example, a resistance element formed of metal, the temperature monitoring element 16 has a positive temperature characteristic. More specifically, the resistance value of the resistance element formed of metal has a positive temperature characteristic. In other words, as the temperature of the resistance element formed of metal is increased, the resistance value of the resistance element formed of metal is increased. The first end of the temperature monitoring element 16 is electrically connected to the pad R10 in the GaN chip 10. The second end of the temperature monitoring element 16 is electrically connected to the pad KS10 in the GaN chip 10.

The Si chip 20 includes a driver 21, a protection circuit, a pad IN20, a pad G20, a pad R20, a pad KS20A, a pad KS20B and a pad VREG20.

The pad G20 provided in the Si chip 20 is electrically connected by a bonding wire 31 to the pad G10 provided in the GaN chip 10. The pad R20 provided in the Si chip 20 is electrically connected by a bonding wire 32 to the pad R10 provided in the GaN chip 10. The pad KS20A provided in the Si chip 20 is electrically connected by a bonding wire 33 to the pad KS10 provided in the GaN chip 10.

The input end of the driver 21 is electrically connected to the pad IN20 in the Si chip 20. The output end of the driver 21 is electrically connected to the pad G20 in the Si chip 20. The driver 21 controls the GaN power element 11 such that when the pulse voltage VP applied to the pad IN20 is high, the GaN power element 11 is on whereas when the pulse voltage VP applied to the pad IN20 is low, the GaN power element 11 is off.

The protection circuit provided in the Si chip 20 is configured to generate a thermal shutdown protection signal using the output of the temperature monitoring element 16, and includes a constant current source, a sample and hold circuit, a comparator 27 and a delay circuit 28.

The constant current source described above is configured to pass a constant current through the temperature monitoring element 16, and includes a P-channel MOS field effect transistor 22, the P-channel MOS field effect transistor 23 and a constant current circuit 24.

The P-channel MOS field effect transistors 22 and 23 form a current mirror circuit. The size of the P-channel MOS field effect transistor 23 is k times the size of the P-channel MOS field effect transistor 22. Here, k is a constant which is greater than 1. The sources and back gates of the P-channel MOS field effect transistors 22 and 23 are electrically connected to the pad IN20 and the input end of the driver 21. The gate and drain of the P-channel MOS field effect transistor 22 and the gate of the P-channel MOS field effect transistor 23 are electrically connected to the first end of the constant current circuit 24. The second end of the constant current circuit 24 is electrically connected to the pads KS20A and KS20B. The drain of the P-channel MOS field effect transistor 23 is electrically connected to the pad R20 and the drain of an N-channel MOS field effect transistor 25.

When the pulse voltage VP applied to the pad IN20 is high, the P-channel MOS field effect transistors 22 and 23 are on, and thus the constant current circuit 24 outputs a constant current Ic, and a constant current k×Ic is output from the drain of the P-channel MOS field effect transistor 23. On the other hand, when the pulse voltage VP applied to the pad IN20 is low, the P-channel MOS field effect transistors 22 and 23 are off, and thus the constant current circuit 24 does not output the constant current Ic, and the constant current k×Ic is not output from the drain of the P-channel MOS field effect transistor 23. In other words, the constant current source which passes the constant current k×Ic through the temperature monitoring element 16 switches whether to pass the constant current k×Ic based on the pulse voltage VP, passes the constant current k×Ic when the GaN power element 11 is on and does not pass the constant current k×Ic when the GaN power element 11 is off. The constant current source is configured not to pass the constant current k×Ic when the GaN power element 11 is off, and thus it is possible to suppress current consumption.

The sample and hold circuit described above is configured to sample the output of the temperature monitoring element 16 (voltage VR applied to the pad R20) when the GaN power element 11 is on, and to hold the output of the temperature monitoring element 16 when the GaN power element 11 is off, and includes the N-channel MOS field effect transistor 25 and a capacitor 26. The sample and hold circuit is provided, and thus even if the pulse width of the pulse voltage VP (length of a high-level period) is short, the output of the temperature monitoring element 16 can be reliably utilized for thermal shutdown protection. The sample and hold circuit is provided, and thus the pulse voltage VP which has a short pulse width (length of a high-level period) is supplied to the delay circuit 28 without being processed, with the result that the pulse voltage VP is prevented from being erroneously regarded as noise to be removed in the delay circuit 28.

As described previously, the drain of the N-channel MOS field effect transistor 25 is electrically connected to the pad R20 and the drain of the P-channel MOS field effect transistor 23. The gate of the N-channel MOS field effect transistor 25 is electrically connected to the output end of the driver 21 and the pad G20. The source of the N-channel MOS field effect transistor 25 is electrically connected to the first end of the capacitor 26. The back gate of the N-channel MOS field effect transistor 25 and the second end of the capacitor 26 are electrically connected to the pads KS20A and KS20B.

The comparator 27 compares a voltage VH output from the sample and hold circuit described above with a reference voltage VREF. The reference voltage VREF may be generated in the Si chip 20, or may be generated outside the Si chip 20 and supplied to the Si chip 20. The value of the voltage VH output from the sample and hold circuit is the product of the resistance value of the temperature monitoring element 16 and the constant current k×Ic when the GaN power element 11 is on. The comparator 27 outputs a high-level voltage when the voltage VH output from the sample and hold circuit is higher than the reference voltage VREF, and outputs a low-level voltage when the voltage VH output from the sample and hold circuit is equal to or less than the reference voltage VREF. Since the resistance value of the temperature monitoring element 16 has a positive temperature characteristic, and the value of the constant current k×Ic and the reference voltage VREF have a temperature characteristic which is flat or can be regarded as being flat, the output of the comparator 27 is switched from low to high, and thus it is possible to detect the overheat of the GaN power element 11.

The delay circuit 28 is a delay circuit which has a noise filtering function, and outputs a voltage VTSD obtained by delaying the output of the comparator 27 for a certain time (for example, 1 μsec) while suppressing a high frequency component which may be included in the output of the comparator 27. The voltage VTSD output from the delay circuit 28 may include a high-level voltage VTSD and a low-level voltage VTSD. The high-level voltage VTSD serves as the thermal shutdown protection signal. For example, the thermal shutdown protection signal stops the operation of the driver 21. For example, a switch for switching the energization and interruption of the constant voltage VREG to the positive power supply end of the driver 21 may be provided, and the switch may be controlled by the thermal shutdown protection signal to interrupt the constant voltage VREG to the positive power supply end of the driver 21.

In the semiconductor device 2 configured as described above, the temperature monitoring element 16 is provided in the GaN chip 10, and thus even when the temperature of the GaN power element 11 provided in the GaN chip 10 rises, from room temperature (25° C.) to a temperature at which thermal shutdown protection needs to be applied, at a rate of about several milliseconds to several tens of milliseconds, it is possible to rapidly perform thermal shutdown protection.

### Application to switching circuit

For example, the semiconductor device 2 described above is used as a part of a switching circuit. Examples of the switching circuit include a switching power supply circuit, a motor driver circuit and the like.

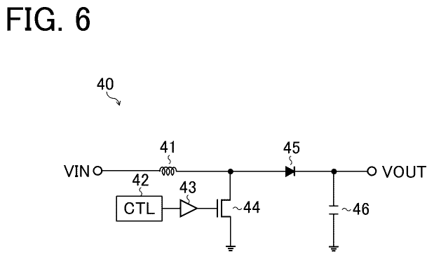

FIG. 6 is a diagram showing a schematic configuration of a step-up DC/DC converter which is an example of the switching power supply circuit. The step-up DC/DC converter 40 shown in FIG. 6 includes an inductor 41, a controller 42, a driver 43, a switching element 44, a diode 45 and a capacitor 46.

When the controller 42 turns on the switching element 44 via the driver 43, a current flows from the application end of an input voltage VIN via the inductor 41 to the switching element 44, and energy is stored in the inductor 41. When the controller 42 switches the switching element 44 from on to off via the driver 43, the energy stored in the inductor 41 is released, a current flows from the inductor 41 to the capacitor 46 via the diode 45 and the capacitor 46 is charged by an output voltage OUT which is higher than the input voltage VIN.

The semiconductor device 2 described above is used as the driver 43 and the switching element 44 in the step-up DC/DC converter 40 shown in FIG. 6.

### Others

It should be considered that the embodiment described above is illustrative in all respects, and not restrictive. The technical scope of the present disclosure is indicated not by the description of the above embodiment but by the scope of claims, and it should be understood that meanings equivalent to the scope of claims and all changes in the scope are included therein.

### Additional Remarks

Additional remarks are provided for the present disclosure the specific configuration example of which is shown in the embodiment described above.

A semiconductor device (2) in the present disclosure includes: a GaN chip (10); an a Si chip (20), the GaN chip includes: a GaN power element (11); and a temperature monitoring element (16) and the Si chip includes: a drive circuit (21) configured to drive the GaN power element; and a protection circuit (22 to 28) configured to generate a thermal shutdown protection signal using an output of the temperature monitoring element (first configuration).

In the semiconductor device of the first configuration described above, the temperature monitoring element is provided in the GaN chip, and thus even when the temperature of the GaN power element provided in the GaN chip rises, from room temperature (25° C.) to a temperature at which thermal shutdown protection needs to be applied, at a rate of about several milliseconds to several tens of milliseconds, it is possible to rapidly perform thermal shutdown protection.

In the semiconductor device of the first configuration described above, the temperature monitoring element may have a positive temperature characteristic (second configuration).

In the semiconductor device of the first or second configuration described above, the protection circuit may include a constant current source (22 to 24) configured to pass a constant current through the temperature monitoring element (third configuration).

In the semiconductor device of the third configuration described above, the constant current source may be configured to pass the constant current when the GaN power element is on, and configured not to pass the constant current when the GaN power element is off (fourth configuration).

In the semiconductor device of the fourth configuration described above, the constant current source may be configured to switch whether to pass the constant current based on a pulse voltage supplied to an input end of the drive circuit (fifth configuration).

In the semiconductor device of any one of the first to fifth configurations described above, the protection circuit may include a sample and hold circuit (25, 26), and the sample and hold circuit may be configured to sample the output of the temperature monitoring element when the GaN power element is on, and to hold the output of the temperature monitoring element when the GaN power element is off (sixth configuration).

In the semiconductor device of the sixth configuration described above, the protection circuit may include: a comparator (27) configured to compare an output of the sample and hold circuit with a reference voltage; and a delay circuit (28) configured to delay an output of the comparator (seventh configuration).

A switching circuit (40) in the present disclosure includes the semiconductor device of any one of the first to seventh configurations described above (eighth configuration).

What is claimed is:

1. A semiconductor device comprising:
a GaN chip; and
a Si chip,
wherein the GaN chip includes:
a GaN power element; and
a temperature monitoring element, and
the Si chip includes:
a drive circuit configured to drive the GaN power element; and
a protection circuit configured to generate a thermal shutdown protection signal using an output of the temperature monitoring element.

2. The semiconductor device according to claim 1,
wherein the temperature monitoring element has a positive temperature characteristic.

3. The semiconductor device according to claim 1,
wherein the protection circuit includes a constant current source configured to pass a constant current through the temperature monitoring element.

4. The semiconductor device according to claim 3,
wherein the constant current source is
configured to pass the constant current when the GaN power element is on, and
configured not to pass the constant current when the GaN power element is off.

5. The semiconductor device according to claim 4,
wherein the constant current source is configured to switch whether to pass the constant current based on a pulse voltage supplied to an input end of the drive circuit.

6. The semiconductor device according to claim 1,
wherein the protection circuit includes a sample and hold circuit, and
the sample and hold circuit is configured
to sample the output of the temperature monitoring element when the GaN power element is on, and
to hold the output of the temperature monitoring element when the GaN power element is off.

7. The semiconductor device according to claim 6,
wherein the protection circuit includes:
a comparator configured to compare an output of the sample and hold circuit with a reference voltage; and
a delay circuit configured to delay an output of the comparator.

8. A switching circuit comprising:
the semiconductor device according to claim 1.

9. A switching circuit comprising:
the semiconductor device according to claim 2.

10. A switching circuit comprising:
the semiconductor device according to claim 3.

11. A switching circuit comprising:
the semiconductor device according to claim 4.

12. A switching circuit comprising:
the semiconductor device according to claim 5.

13. A switching circuit comprising:
the semiconductor device according to claim 6.

14. A switching circuit comprising:
the semiconductor device according to claim 7.
